(19) United States
(12) Patent Application Publication
(10) Pub. No.: US 2015/0340322 A1
(43) Pub. Date: Nov. 26, 2015

(54) RF SWITCH STRUCTURE HAVING REDUCED OFF-STATE CAPACITANCE

(71) Applicant: RF Micro Devices, Inc., Greensboro, NC (US)

(72) Inventors: Philip W. Mason, Greensboro, NC (US); Michael Carroll, Jamestown, NC (US); Julio C. Costa, Oak Ridge, NC (US)

(21) Appl. No.: 14/721,531

(22) Filed: May 26, 2015

Related U.S. Application Data
(60) Provisional application No. 62/002,387, filed on May 23, 2014.

(51) Int. Cl. H01L 23/532; H01L 23/522; H01L 23/528; H01L 27/088

(52) U.S. Cl. CPC H01L 23/5329; H01L 27/088; H01L 23/5226; H01L 23/528; H01L 23/5222

(57) ABSTRACT

An RF switch structure having reduced off-state capacitance is disclosed. The RF switch structure includes an RF switch branch having at least three transistors coupled in series within a device layer. Inter-metal dielectric (IMD) layers are disposed over the device layer. At least one of the IMD layers has an effective dielectric constant that is lower than 3.9. In one exemplary embodiment, the IMD layers are made of silicon dioxide having micro-voids. In another exemplary embodiment, the IMD layers are made of silicon dioxide that includes carbon doping. In either exemplary embodiment, an effective dielectric constant ranges from about 3.9 to around 2.0. In another exemplary embodiment, the IMD layers are made of silicon dioxide having trapped air bubbles that provide an effective dielectric constant that ranges from about 2.0 to 1.1.

### RELATED APPLICATIONS

This application claims the benefit of U.S. provisional patent application No. 62/002,387, filed May 23, 2014, the disclosure of which is incorporated herein by reference in its entirety.

### FIELD OF THE DISCLOSURE

The present disclosure relates to RF switches that include at least one inter-metal dielectric layer.

### BACKGROUND

Consumer demand for wireless communication is ever increasing worldwide, placing a burden on the existing cellular infrastructure. In Europe, the increased demand led regulators to create the Digital Cellular System (DCS) cellular telephone band. DCS utilizes Global System for Mobile Communications (GSM) baseband technology at carrier frequencies near 1.8 GHZ.

Also in response to consumer demand, cellular telephone manufacturers strive to reduce the size and weight of their phones. With the introduction of DCS, and the creation of dual-band GSM/DCS phones, the quest for ever smaller components has intensified.

In this regard, even already relatively small components such as RF switches need to be reduced in size. However, a reduction in size confines traditional metallization layers such that parasitic capacitance increases, causing RF isolation to be diminished, which in turn reduces the performance of the RF switch.

FIG. 1 is a schematic of a related art RF switch branch 10 made up of a stack of four transistors M1 to M4. Each of the four transistors M1 to M4 has a drain-to-source capacitance, which in this case is represented by C1 to C4, respectively. FIG. 2 is a cross-section diagram of a physical layout of a portion of a related art RF switch structure 12 that includes two transistors M1 and M2 from the related art RF switch branch of FIG. 1. The transistor M1 and the transistor M2 are formed within a device layer 14.

In detail, the transistor M1 includes a source S1, a gate G1, and a drain D1. A current conducting channel CH1 is formed under the gate 01 when the transistor M1 is turned on. Similarly, the transistor M2 includes a source S2, a gate G2, and a drain D2. A current conducting channel CH2 is formed under the gate G2 when the transistor M2 is turned on. A first shallow trench isolation region (STIR1) resides within the device layer 14 adjacent to the first source S1. A second shallow trench isolation region (STIR2) resides within the device layer 14 adjacent to and between the first drain D1 and the second source S2. A third shallow trench isolation region (STIR3) resides within the device layer 14 adjacent to the second drain D2. Also note that it is typical for the gate G1 and the gate G2 to be made of poly silicon.

A buried oxide (BOX) layer 16 resides between the device layer 14 and a handle wafer 18 that is a substrate for the RF switch structure 12. Inter-metal dielectric (IMD) layers 20 are disposed over the device layer 14. The IMD layers 20 include a first metal layer 22 comprising a first conductor E1, a second conductor E2, and a third conductor E3. The IMD layers 20 further includes a second metal layer 24 comprised of a fourth conductor E4 and a fifth conductor E5. The conductors E1 to E5 are traditionally made of aluminum. The IMD layers 20 comprise intra-metal dielectrics. For example, a first intra-metal dielectric resides between the first conductor E1 and the second conductor E2, while a second intra-metal dielectric resides between the second conductor E2 and the third conductor E3. A third intra-metal dielectric resides between the fourth conductor E4 and the fifth conductor E5.

A first via V1 electrically couples the first conductor E1 to the source S1, a second via V2 electrically couples the second conductor E2 to the first drain D1, whereas a third via V3 couples the second conductor E2 to the second source S2. As such, the first drain D1 and the second source S2 are electrically coupled together. A fourth via V4 electrically couples the third conductor E3 to the second drain D2. A fifth via V5 electrically couples the fourth conductor E4 to the first conductor E1, whereas a sixth via V6 couples the fifth conductor E5 to the third conductor E3. Traditionally, the vias V1 to V6 have plugs made of tungsten.

Traditionally, silicon dioxide is used for the dielectric material comprising the IMD layers 20. The silicon dioxide gives the IMD layers 20 an effective dielectric constant of 3.9. As a result, a parasitic capacitance C1A created between the first conductor E1 and the second conductor E2 is higher than desired, especially since the parasitic capacitance C1A is in parallel with the drain-to-source capacitance C1 (FIG. 1).

Similarly, a parasitic capacitance C1B created between the second conductor E2 and the third conductor E3 is also higher than desired due to the relatively large effective dielectric constant of 3.9 that is inherent to the silicon dioxide. The parasitic capacitance C1B is in parallel with the drain-to-source capacitance C2 (FIG. 1).

Another parasitic capacitance C2A created between the fourth conductor E4 and the fifth conductor E5 also contributes an off-state capacitance C_{OFF} for the RF switch branch 10 (FIG. 1). Other parasitic capacitances (not shown) exist between the first gate G1 and the first via V1, the first gate G1 and the second via V2, the first gate G1 and the first source S1, the first gate G1 and the first drain D1, the first gate G1 and the first conductor E1, and the first gate G1 and the second conductor E2. Yet, other parasitic capacitances (not shown) exist between the second gate G2 and the third via V3, the second gate G2 and the fourth via V4, the second gate G2 and the second source S2, the second gate G2 and the second drain D2, the second gate G2 and the second conductor E2, and the second gate G2 and the third conductor E3. An off-state capacitance C_{OFF} would be reduced provided that the parasitic capacitances listed above are reduced.

A figure of merit for the switch branch 10 is a product of an on-state resistance R_{ON} of the transistors M1 to M4 and the off-state capacitance C_{OFF}. It is desirable for the figure of merit to have a low value to reduce switching time. The on-state resistance is a predetermined value for this disclosure. Therefore, what is needed is an RF structure that provides a reduction of the off-state capacitance C_{OFF} that is made up of the above listed parasitic capacitances.

### SUMMARY

An RF switch structure having reduced off-state capacitance is disclosed. The RF switch structure includes an RF switch branch having at least three transistors coupled in series within a device layer. Inter-metal dielectric (IMD) layers are disposed over the device layer. The IMD layers have an effective dielectric constant that is lower than 3.9, which reduces parasitic capacitance associated with metal layers embedded within the IMD layers by at least 40%.

In one exemplary embodiment, the IMD layers are made of silicon dioxide having micro-voids that provide the IMD layers with an effective dielectric constant that ranges from about 3.9 to around 2.0. In another exemplary embodiment, the IMD layers are made of silicon dioxide having trapped air bubbles that provide the IMD layers with an effective dielectric constant that ranges from about 2.0 to around 1.1. In yet another exemplary embodiment, the IMD layers are made of silicon dioxide that includes carbon doping sufficient to provide the IMD layers with an effective dielectric constant that ranges from about 3.9 to around 2.0.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure, and together with the description, serve to explain the principles of the disclosure.

FIG. 1 is a schematic of a related art RF switch branch made up of a stack of four transistors.

FIG. 2 is a cross-section diagram of a physical layout of a portion of a related art switch structure that includes two transistors from the related art RF switch branch of FIG. 1.

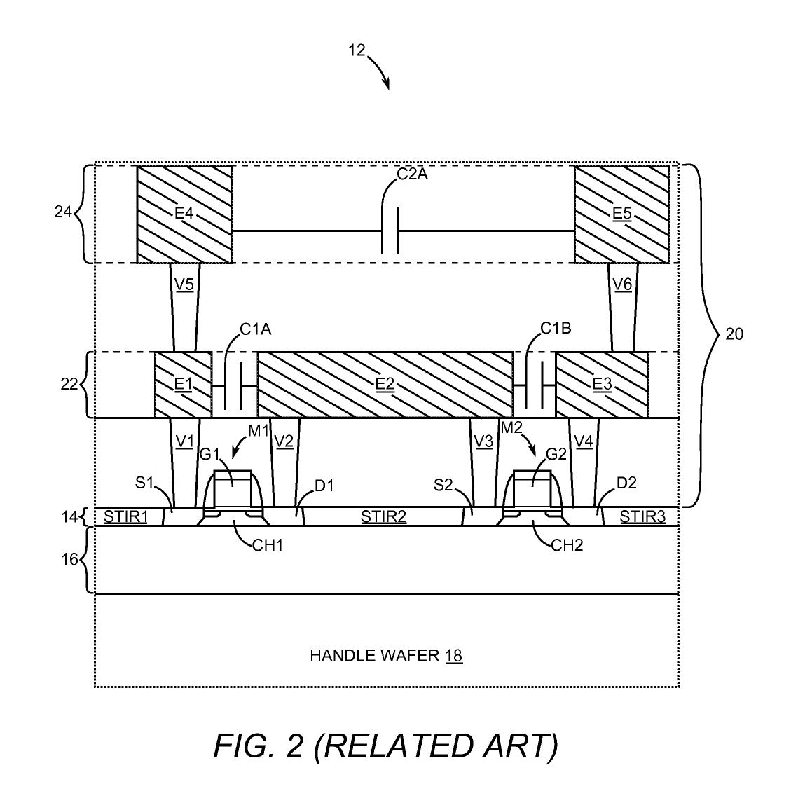

FIG. 3 is a cross-section diagram of a physical layout of a portion of an RF switch structure that in accordance with the present disclosure includes inter-metal dielectric layers having micro-voids that provide reduced off-state capacitance.

FIG. 4 is a cross-section diagram of a physical layout of a portion of an RF switch structure that in accordance with the present disclosure includes inter-metal dielectric layers having trapped air bubbles that provide reduced off-state capacitance.

FIG. 5 is a cross-section diagram of a physical layout of a portion of an RF switch structure that in accordance with the present disclosure includes inter-metal dielectric layers having carbon doping that provides reduced off-state capacitance.

### DETAILED DESCRIPTION

The embodiments set forth below represent the necessary information to enable those skilled in the art to practice the disclosure and illustrate the best mode of practicing the disclosure. Upon reading the following description in light of the accompanying drawings, those skilled in the art will understand the concepts of the disclosure and will recognize applications of these concepts not particularly addressed herein. It should be understood that these concepts and applications fall within the scope of the disclosure and the accompanying claims.

It will be understood that when an element such as a layer, region, or substrate is referred to as being “over,” “on,” “in,” or extending “onto” another element, it can be directly over, directly on, directly in, or extend directly onto the other element, or intervening elements may also be present. In contrast, when an element is referred to as being “directly over,” “directly on,” “directly in,” or extending “directly onto” another element, there are no intervening elements present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

In general, and in accordance with the present disclosure, a dielectric material having a low dielectric constant of less than 3.9 is substituted for a standard silicon dioxide material having a substantially higher dielectric constant of 3.9. The dielectric material required by the present disclosure is known as a low-k material in the electronics industry, and for the purpose of this disclosure a low-k material has a dielectric constant lower than 3.9. The lower dielectric constant reduces the amount of electric field lines that can form between conductors within an inter-metal dielectric layer. Thus, any off-state capacitance formed between the conductors comprising metallization within the IMD layers is significantly reduced. As a result, the figure of merit from the product of the on-state resistance and the off-state capacitance is lowered in value to a desirable level.

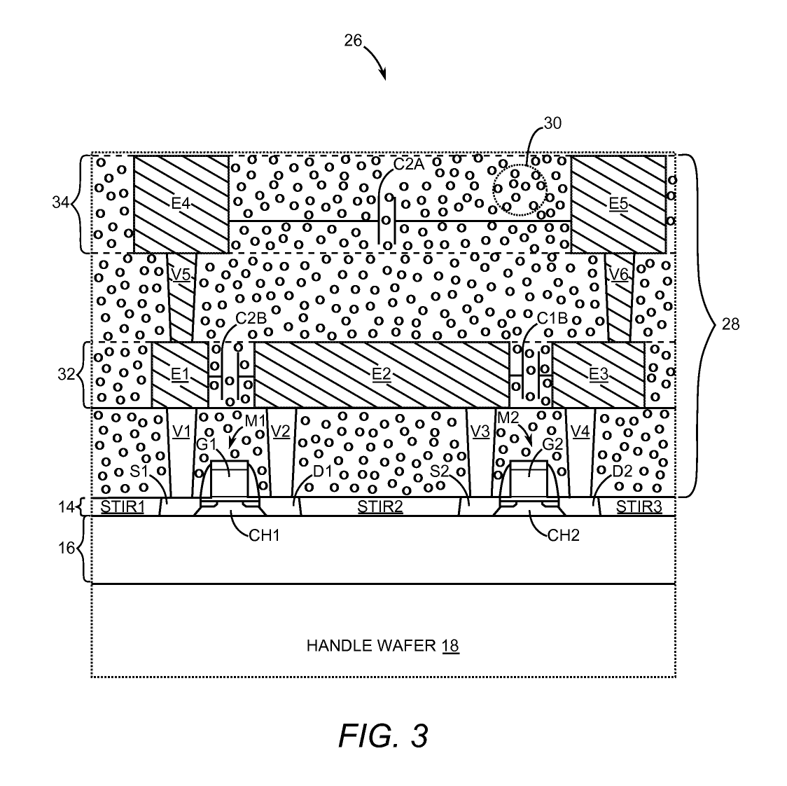

In this regard, FIG. 3 is a cross-section diagram of a physical layout of a portion of an RF switch structure 26 that in accordance with the present disclosure includes inter-metal dielectric (IMD) layers 28 having micro-voids 30 that provide reduced off-state capacitance. A sample of the micro-voids 30 that are spaced throughout the IMD layers 28 is shown enclosed within a dashed circle. The micro-voids 30 depicted in FIG. 3 are not drawn to scale and would be invisible to the naked eye. In at least one embodiment, the micro-voids 30 have dimensions approaching atomic scale. Further still, the micro-voids 30 have a sufficient total volume to reduce an effective dielectric constant for the IMD layers 28 to less than 3.9. In at least one embodiment, the effective dielectric constant ranges between about 3.9 to around 2.0.

Moreover, a first metal layer 32 comprised of conductors E1 to E3, and a second metal layer 34 comprised of conductor E4 and conductor E5 are made of copper. Similarly, the vias V5 and V6 have copper plugs as opposed to the tungsten plugs that are traditionally used. Vias V1 to V4 remain plugged with tungsten due to copper being incompatible with the transistors M1 and M2.

The substitution of copper for aluminum is advantageous because the conductivity of copper is greater than the conductivity of aluminum. Therefore, the result of substituting copper for aluminum is reduced insertion loss for the RF switch structure 26. Further still, the first metal layer 32 and the second metal layer 34 have substantially reduced dimensions in comparison to conventional aluminum metal layers that provide a conductive path for a current that flows through a similarly configured switch branch. In this embodiment and in the embodiments that follow, the present disclosure implements a combination of reductions in both the metal-to-metal spacing and the die size to both improve the RF switch performance and shrink a product's switch branch size.

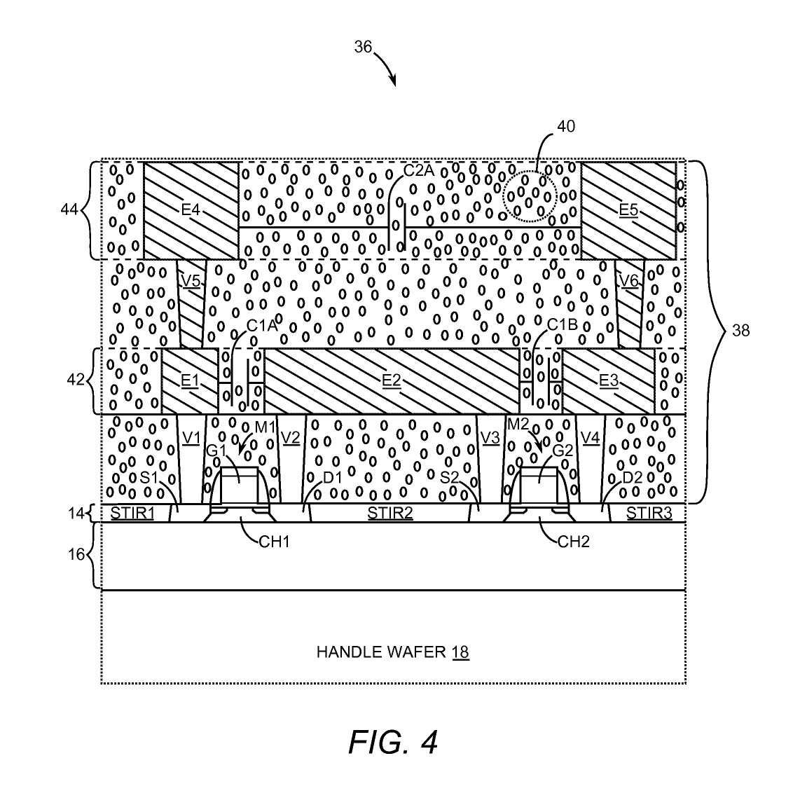

FIG. 4 is a cross-section diagram of a physical layout of a portion of an RF switch structure 36 that in accordance with the present disclosure includes IMD layers 38 having trapped air bubbles 40 that provide reduced off-state capacitance. A sample of the trapped air bubbles 40 that are spaced throughout the IMD layers 38 is shown enclosed within a dashed circle. The trapped air bubbles 40 have a sufficient total volume to reduce an effective dielectric constant for the IMD layers 38 to less than 3.9 and typically less than 2.0. In at least one embodiment, the effective dielectric constant ranges between about 2.0 to around 1.1.

Moreover, a first metal layer 42 comprised of conductors E1 to E3 and a second metal layer 44 comprised of conductor E4 and conductor E5 are made of copper. Similarly, the vias V5 and V6 have copper plugs as opposed to the tungsten plugs that are traditionally used. As with the embodiment of FIG. 3, the substitution of copper for aluminum is advantageous because the conductivity of copper is greater than the conductivity of aluminum. Therefore, the result of substituting copper for aluminum is reduced insertion loss for the RF switch structure 36. Vias V1 to V4 remain plugged with tungsten due to copper being incompatible with the transistors M1 and M2.

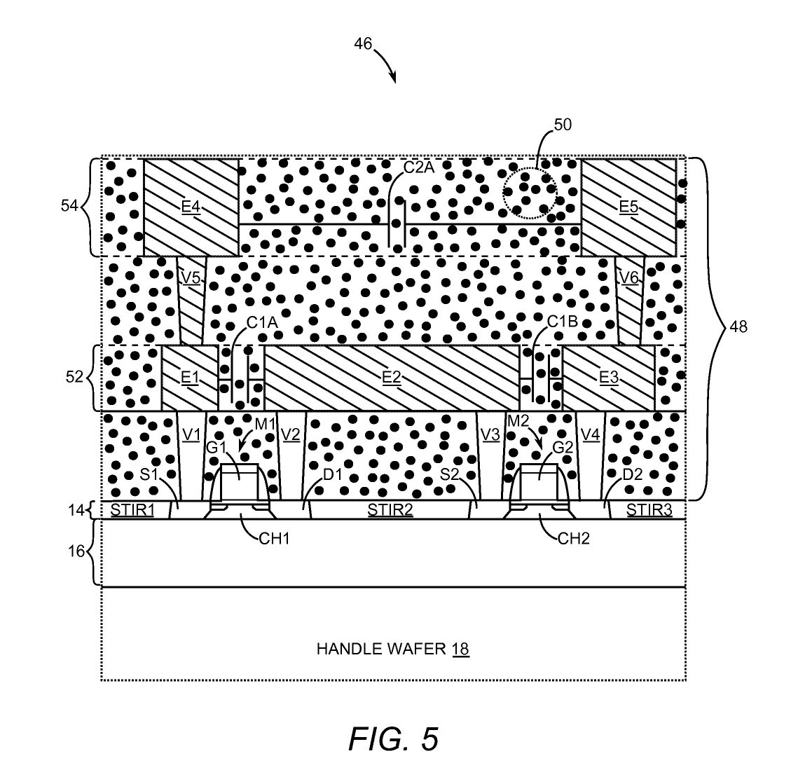

FIG. 5 is a cross-section diagram of a physical layout of a portion of an RF switch structure 46 that in accordance with the present disclosure includes IMD layers 48 having carbon doping 50 that provides reduced off-state capacitance. A sample of the carbon doping 50 that is spaced throughout the IMD layers 48 is enclosed within a dashed circle. The carbon doping 50 depicted in FIG. 5 is not drawn to scale and would be invisible to the naked eye. In at least one embodiment, the carbon doping 50 has dimensions approaching atomic scale. Further still, the carbon doping 50 is in sufficient ratio in comparison to the dielectric material of the IMD layers 48 that the carbon doping reduces an effective dielectric constant for the IMD layers 48 to less than 3.9. In at least one embodiment, the effective dielectric constant ranges between about 3.9 to around 2.0. The carbon doping 50 can be carbon nanostructures such as carbon allotropes that include but are not limited to carbon nanotubes and graphene.

Moreover, a first metal layer 52 comprised of conductors E1 to E3, and a second metal layer 54 comprised of conductor E4 and conductor E5 are made of copper. Similarly, the vias V5 and V6 have copper plugs as opposed to the tungsten plugs that are traditionally used. As with the embodiments of FIG. 3 and FIG. 4, the substitution of copper for aluminum is advantageous because the conductivity of copper is greater than the conductivity of aluminum. Therefore, the result of substituting copper for aluminum is reduced insertion loss for the RF switch structure 46. Vias V1 to V4 remain plugged with tungsten due to copper being incompatible with the transistors M1 and M2.

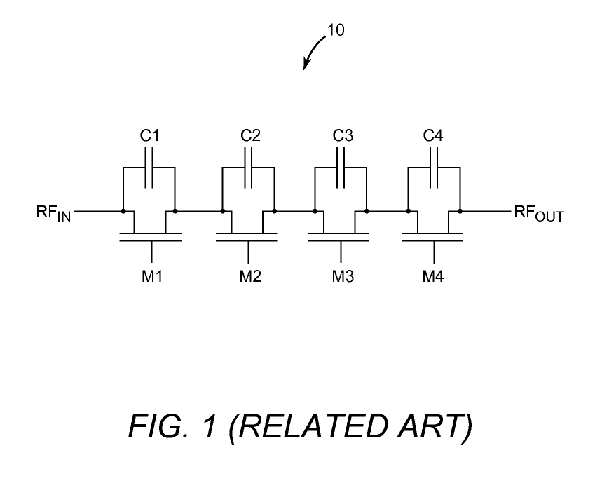

In at least one embodiment, a switch branch such as switch branch 10 (FIG. 1) comprised of either of the RF switch structure 26 (FIG. 3), the RF switch structure 36 (FIG. 4), or the RF switch structure 46 (FIG. 5) withstands at least 10 V root mean square (RMS) without breaking down when the at least three transistors are in an off-state. Also, it is to be understood that a dielectric material modified with any of the micro-voids 30 (FIG. 3), the trapped air bubbles 40 (FIG. 4), or the carbon doping 50 can be silicon dioxide. As such, RF silicon-on-insulator (SOI) switch technology incorporating embodiments of the present disclosure will have improved RF performance of RF switches and associated products used in RF applications.

Those skilled in the art will recognize improvements and modifications to the embodiments of the present disclosure. All such improvements and modifications are considered within the scope of the concepts disclosed herein and the claims that follow.

What is claimed is:

1. An RF switch structure having reduced off-state capacitance comprising:
an RF switch branch having at least three transistors coupled in series within a device layer; and
at least one inter-metal dielectric (IMD) layer disposed over the device layer, wherein the at least one IMD layer has an effective dielectric constant that is lower than 3.9.

2. The RF switch structure having reduced off-state capacitance of claim 1 wherein the at least one IMD layer is made of a material having an effective dielectric constant that ranges from about 3.9 to around 2.0.

3. The RF switch structure having reduced off-state capacitance of claim 1 wherein the at least one IMD layer is made of a material having an effective dielectric constant that ranges from about 2.0 to around 1.1.

4. The RF switch structure having reduced off-state capacitance of claim 1 wherein the at least one IMD layer comprises a low dielectric constant material having a dielectric constant that is lower than 2.2 that reduces parasitic capacitance associated with metal layers embedded within the at least one IMD layer by at least 40%.

5. The RF switch structure having reduced off-state capacitance of claim 1 wherein the at least one IMD layer is made of silicon dioxide having micro-voids that provide the at least one IMD layer with an effective dielectric constant that ranges from about 3.9 to around 2.0.

6. The RF switch structure having reduced off-state capacitance of claim 1 wherein the at least one IMD layer is made of silicon dioxide having trapped air bubbles that provide the at least one IMD layer with an effective dielectric constant that ranges from about 2.0 to around 1.1.

7. The RF switch structure having reduced off-state capacitance of claim 1 wherein the at least one IMD layer is made of silicon dioxide that includes carbon doping sufficient to provide the at least one IMD layer with an effective dielectric constant that ranges from about 3.9 to around 2.0.

8. The RF switch structure having reduced off-state capacitance of claim 1 wherein metal layers in the at least one IMD layer are made of copper to provide a conductive path for a current that flows through the RF switch branch when the at least three transistors are in an on state.

9. The RF switch structure having reduced off-state capacitance of claim 8 wherein the metal layers have substantially reduced dimensions in comparison to conventional aluminum metal layers that provide a conductive path for a current that flows through a similarly configured switch branch.

10. The RF switch structure having reduced off-state capacitance of claim 1 wherein the RF switch branch withstands at least 10 V root mean square (RMS) without breaking down when the at least three transistors are in an off-state.

11. A method of fabricating an RF switch structure having reduced off-state capacitance comprising:
providing a device layer having an RF switch branch with at least three transistors coupled in series; and
disposing at least one inter-metal dielectric (IMD) layer over the device layer, wherein the at least one IMD layer has an effective dielectric constant that is lower than 3.9.

12. The method of fabricating an RF switch structure having reduced off-state capacitance of claim 11 wherein the at least one IMD layer is made of a material having an effective dielectric constant that ranges from about 3.9 to around 2.0.

13. The method of fabricating an RF switch structure having reduced off-state capacitance of claim 11 wherein the at least one IMD layer is made of a material having an effective dielectric constant that ranges from about 2.0 to around 1.1.

14. The method of fabricating an RF switch structure having reduced off-state capacitance of claim 11 wherein the at least one IMD layer comprises a low dielectric constant material having a dielectric constant that is lower than 2.2 that reduces parasitic capacitance associated with metal layers embedded within the at least one IMD layer by at least 40%.

15. The method of fabricating an RF switch structure having reduced off-state capacitance of claim 11 wherein the at least one IMD layer is made of silicon dioxide having micro-voids that provide the at least one IMD layer with an effective dielectric constant that ranges from about 3.9 to around 2.0.

16. The method of fabricating an RF switch structure having reduced off-state capacitance of claim 11 wherein the at least one IMD layer is made of silicon dioxide having trapped air bubbles that provide the at least one IMD layer with an effective dielectric constant that ranges from about 2.0 to around 1.1.

17. The method of fabricating an RF switch structure having reduced off-state capacitance of claim 11 wherein the at least one IMD layer is made of silicon dioxide that includes carbon doping sufficient to provide the at least one IMD layer with an effective dielectric constant that ranges from about 3.9 to around 2.0.

18. The method of fabricating an RF switch structure having reduced off-state capacitance of claim 11 wherein metal layers in the at least one IMD layer are made of copper to provide a conductive path for a current that flows through the RF switch branch when the at least three transistors are in an on-state.

19. The method of fabricating an RF switch structure having reduced off-state capacitance of claim 18 wherein the metal layers have substantially reduced dimensions in comparison to conventional aluminum metal layers that provide a conductive path for a current that flows through a similarly configured switch branch.

20. The RF switch structure having reduced off-state capacitance of claim 11 wherein the RF switch branch withstands at least 10 V root mean square (RMS) without breaking down when the at least three transistors are in an off-state.
